(19) United States
(12) Patent Application Publication
(10) Pub. No.: US 2007/0077717 A1
(43) Pub. Date: Apr. 5, 2007

(54) Method for forming transistor of semiconductor device

(75) Inventors: Jae Soo Kim, Gyunggi-do (KR); Hye Jin Seo, Gyunggi-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Gyunggi-do (KR)

(21) Appl. No.: 11/303,225

(22) Filed: Dec. 15, 2005

(30) Foreign Application Priority Data
Sep. 30, 2005 (KR) 2005-92374

(51) Int. Cl. H01L 21/336

(52) U.S. Cl. 438/303; 438/595; 438/763

(57) ABSTRACT

A method for forming a transistor of a semiconductor device includes forming a spacer oxide film having a uniform thickness i at a high speed. The method includes forming a plurality of gate stacks on a semiconductor substrate; and forming a spacer oxide film on a plurality of the gate stacks by alternately supplying trimethyl aluminum in a gaseous state and tris-(tert-alkoxy)-silanol in a gaseous state to the semiconductor substrate.

### BACKGROUND OF THE INVENTION

The present invention relates to a method for forming a transistor of a semiconductor device, in which a spacer oxide film having a uniform thickness is formed at a high speed.

The present invention relates to a method for forming a transistor of a semiconductor device, in which a spacer oxide film having a uniform thickness is formed at a high speed.

Transistors of a semiconductor device, particularly peri-transistors comprising PMOS transistors and NMOS transistors, have electrical characteristics which highly depend on the uniformity of the thickness of gates. That is, gates having a uniform thickness which are formed in a single wafer or different wafers, uniformly improve electrical characteristics of a semiconductor device, thereby allowing the semiconductor device to be more robustly operated and improving yield of the semiconductor device.

Hereinafter, a conventional method for forming a transistor of a semiconductor device having the above gates will be described.

First, a plurality of gate stacks comprising a gate insulating film, a gate conductive film, and a hard mask film are formed on a semiconductor substrate, and a low-concentration impurity is injected into the semiconductor substrate, thereby forming LDD regions on the semiconductor substrates at both sides of the gate stacks.

Thereafter, an oxide layer, such as a TEOS layer, is deposited on the semiconductor substrate using a CVD such as LPCVD, thereby forming a spacer oxide film on the gate stacks. Blanket etching is performed on the spacer oxide film, thereby forming gate spacers at both side walls of the gate stacks. Thus, a plurality of gates having gate stacks and gate spacers are formed on the semiconductor substrate.

Then, a high-concentration impurity is injected into the semiconductor substrate at both sides of the gates, thereby forming sources/drains. Consequently, a transistor of a semiconductor device having an LDD structure is produced.

The above conventional method has been applied to a manufacturing method of peri-transistors having PMOS transistors and NMOS transistors requiring high-speed operation, and applied to other manufacturing processes of semiconductor devices.

As there is a current trend toward the development of high-integration and hyperfine semiconductor devices, the density of a plurality of gate stacks formed on semiconductor substrates having the same dimensions is increased. Furthermore, since regions in which a large number of the gate stacks are densely arranged and regions in which a small number of gate stacks are sparsely arranged are simultaneously present on a single semiconductor substrate, the densities of the gate stacks in the two regions are different.

Accordingly, regardless of the densities of the gate stacks, gate spacers having a uniform thickness need to be formed on side walls of the gate stacks in all regions, and a plurality of gates comprising the gate stacks and the gate spacers also need to be formed on the semiconductor substrate to a uniform thickness. Thus a transistor of a semiconductor device comprising the gates can have uniformly improved electrical characteristics.

However, according to the above conventional method for forming the transistor, when a spacer oxide film is formed by a CVD such as LPCVD and gate spacers are formed by blanket-etching the spacer oxide film, the spacer oxide film formed by CVD cannot have a uniform thickness on a semiconductor substrate on which a plurality of gate stacks are arranged at different densities according to regions, and thus the gate spacers formed at side walls of the gate stacks in all regions cannot have a uniform thickness. That is, when the spacer oxide film is formed by CVD, the spacer oxide film in regions where a large number of the gate stacks are densely arranged has a small thickness, and the spacer oxide film in regions where a small number of the gate stacks are sparsely arranged has a large thickness. Therefore, the gate spacers obtained by blanket-etching the spacer oxide film on a single semiconductor substrate have different thicknesses according to regions, and the gate spacers on different semiconductor substrates have different thicknesses.

The gate spacers formed on different regions of a given substrate often tends to have different thicknesses. Similarly, the gate spacers formed on different substrates tends to have different thicknesses. As a result, the gate stacks and spacers of different transistors at different regions commonly have different thicknesses. Thus, electrical characteristics of a transistor of a semiconductor device, for example threshold voltage (Vt) characteristics of a PMOS, may not uniform. That is, the Vt difference among the PMOS transistors in different regions is increased.

Accordingly, in the above conventional method, electrical characteristics of the transistor of the semiconductor device, such as Vt characteristics of a PMOS, are not uniform, are deteriorated, and the yield of the semiconductor device is lowered. Further, the transistor of the semiconductor device, particularly a peri-transistor (transistors formed in a periphery of the substrate), may more likely malfunction.

In order to solve the above problems, instead of a CVD such as LPCVD, atomic layer deposition (ALD) is employed by the formation of the spacer oxide film, so as to form gate spacers and gates having a uniform thickness.

However, as will be apparent to those skilled in the art, ALD has such a low deposition speed that only a single atomic layer is grown per cycle of ALD, and mass production of semiconductor devices is difficult.

Accordingly, the development of a process for forming a spacer oxide film having a uniform thickness at a high speed regardless of the density of a plurality of gate stacks is desirable.

### BRIEF SUMMARY OF THE INVENTION

The present invention relates to a method for forming a transistor of a semiconductor device in which a spacer oxide film having a uniform thickness is formed at a high speed regardless of density of a plurality of gate stacks.

In accordance with one aspect of the present invention, a method for forming a transistor of a semiconductor device comprises forming a plurality of gate stacks on a semiconductor substrate and forming a spacer oxide film on a plurality of the gate stacks by alternately supplying trimethyl aluminum in a gaseous state and tris-(tert-alkoxy)-silanol in a gaseous state to the semiconductor substrate.

After the formation of the gate stacks, the surfaces of a plurality of the gate stacks is oxidized. LDD regions are formed at both sides of the gate stacks on the semiconductor substrate. A buffer oxide film and a spacer nitride film are sequentially formed on a plurality of the gate stacks.

In one implementation, the tris-(tert-alkoxy)-silanol is tris-(tert-butoxy)-silanol or tris-(tert-pentoxy)-silanol.

Furthermore the formation of the spacer oxide film may preferably be carried out at less than atmospheric pressure and at a temperature of 225˜250° C.

The method, before the formation of the spacer oxide film, may further comprise washing the surface of the semiconductor substrate with an aqueous acid solution. Preferably, the aqueous acid solution may be an aqueous HF solution.

### BRIEF DESCRIPTION OF THE DRAWINGS

FIGS. 1A-1D are schematic sectional views illustrating a method for forming a transistor of a semiconductor device in accordance with an embodiment of the present invention; and

FIG. 2 is a view illustrating a reaction mechanism of forming a spacer oxide film according to the method shown in FIGS. 1A-1D.

### DETAILED DESCRIPTION OF THE INVENTION

The present invention will be described in detail with reference to the accompanying drawings and corresponding embodiments thereof. These embodiments are described to illustrate the invention to those ordinary skilled in the art and should not be used to limit the scope of the present invention.

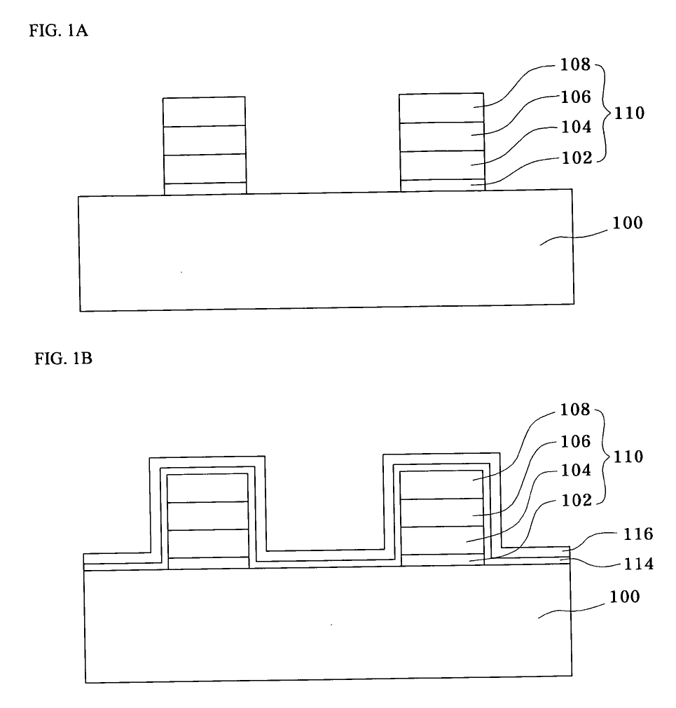

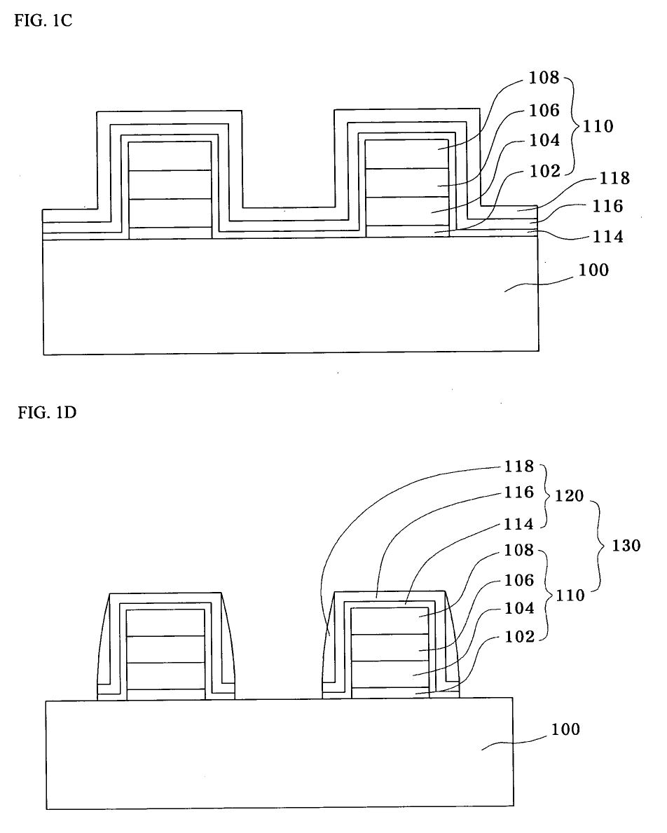

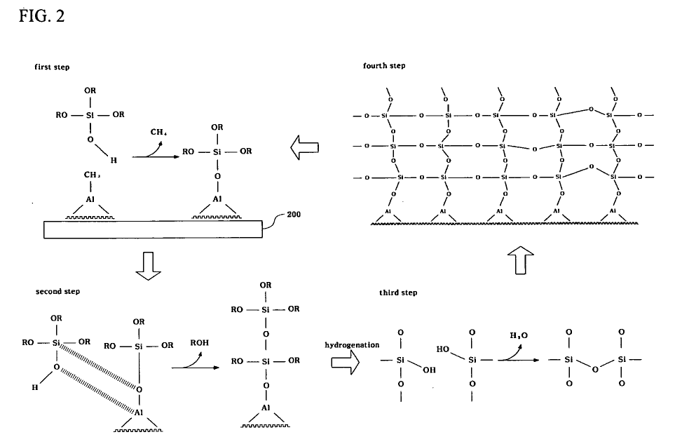

FIGS. 1A-1D are schematic sectional views illustrating a method for forming a transistor of a semiconductor device in accordance with an embodiment of the present invention, and FIG. 2 is a view illustrating a reaction mechanism for forming a spacer oxide film according to the method shown in FIGS. 1A-1D.

In order to form a transistor of a semiconductor device in accordance with this embodiment of the present invention, first, as shown in FIG. 1A, a plurality of gate stacks 110 are formed on a semiconductor substrate 100. More particularly, the gate stacks 110 are formed by sequentially laminating a gate insulating film 102 such as an oxide film, a gate conductive film 104 such as a poly silicon film, a metal silicide film 106 such as a tungsten silicide film, and a hard mask film 108 such as a nitride film, and by sequentially patterning the hard mask film 108, the metal silicide film 106, the gate conductive film 104, and the gate insulating film 102 by a photo etching process using a photoresist film (not shown).

After a plurality of the gate stacks 110 are formed, the surfaces of the gate stacks 110 are lightly oxidized so as to repair the damage to the gate stacks 110 resulting from the etching process. Then, a low-concentration impurity is injected into the semiconductor substrate 100, thereby forming LDD regions (not shown) on the semiconductor substrate 100 at both sides of the gate stacks 110.

Thereafter, as shown in FIG. 1B, a buffer oxide film 114 and a spacer nitride film 116 are sequentially formed on the semiconductor substrate 100, including on the gate stacks 110. The buffer oxide film 114 is provided between the nitride film 116 and the substrate 100 to reduce the high stress that would otherwise result if the nitride film is directly formed on the substrate 100. The spacer nitride film 116 consists of silicon nitride (Si₃N₄) and serves as a barrier in an impurity injection step and an etching step that will be subsequently performed on the substrate.

Referring to FIG. 1C, after the spacer nitride film 116 is formed a spacer oxide film 118 is deposited on the semiconductor substrate 100 including over the gate stacks 110, the buffer oxide film 114, and the spacer nitride film 116. More particularly, in this embodiment the spacer oxide film 118 is not formed by a CVD such as LPCVD or ALD as is conventionally employed, but is formed by pulse dielectric layer (PDL) deposition in which trimethyl aluminum in a gaseous state and tris-(tert-alkoxy)-silanol in a gaseous state are alternately supplied to the substrate 100. The spacer oxide film 118, nitride film 116, and buffer oxide film 114 are etched at selected locations to provide a gate spacer 120, as shown in FIG. 1D. Accordingly, a structure 130 having the gate spacer 120, the gate insulating film 102, the conductive film 104, the silicide film 106, and the hard mask film 108 is obtained.

Hereinafter, with reference to FIG. 2, a reaction mechanism of forming an oxide layer using PDL deposition will be described.

As shown in FIG. 2, trimethyl aluminum in a gaseous state is supplied to a target layer 200 on which the oxide layer will be formed. Then, silicon of the target layer 200 and aluminum of trimethyl aluminum react with each other, thereby forming a methyl aluminum film on the surface of the target layer 200.

Thereafter, tris-(tert-alkoxy)-silanol in a gaseous state, such as tris-(tert-butoxy)-silanol or tris-(tert-pentoxy)-silanol in a gaseous state, is supplied to the target layer 200 that is coated with the methyl aluminum film. At this step, tris-(tert-alkoxy)-silanol and the methyl aluminum film coating on the surface of the target layer 200 react with each other so that aluminum of the methyl aluminum film and oxygen of tris-(tert-alkoxy)-silanol bond to each other (with reference to first step of FIG. 2).

After one molecule of methyl aluminum and one molecule of tris-(tert-alkoxy)-silanol react with each other, other molecules of tris-(tert-alkoxy)-silanol may diffuse and additionally react with the above aluminum-oxygen bond due to the catalytic action of aluminum. That is, aluminum on the surface of the target layer 200 does not react with only one molecule of tris-(tert-alkoxy)-silanol, but reacts with multiple molecules of tris-(tert-alkoxy)-silanol (with reference to second step of FIG. 2).

After a siloxane polymer is formed by the reaction of multiple molecules of tris-(tert-alkoxy)-silanol with aluminum on the surface of the target layer 200 through the above steps, molecules of siloxane polymer react with each other, thereby forming crosslinkage between the molecules of siloxane polymer (with reference to third step of FIG. 2). The above crosslinkage exhibits a self-regulating property, in which the silicon-oxygen bonds combined with aluminum on the surface of the target layer 200, which are formed throughout the overall regions of the target layer 200, have a uniform number.

Through the above process, an aluminum film, i.e., an aluminum oxide film, is formed on the target layer 200, and an oxide film is formed on the aluminum film (with reference to fourth step of FIG. 2). An oxide film having a desired thickness is formed by repeating the supplying of trimethyl aluminum in a gaseous state and tris-(tert-alkoxy)-silanol in a gaseous state in alternate manner.

When the oxide film is formed by PDL deposition according to the above reaction mechanism, multiple molecule layers of the oxide film are grown on the semiconductor substrate per cycle due to the catalytic action of aluminum. Accordingly, PDL deposition can form an oxide film at a higher speed than conventional ALD (approximately one hundred times as fast as ALD). Simultaneously, PDL deposition exhibits the self-regulating property by which the oxide film having a uniform thickness is formed throughout all regions on the substrate, like ALD.

Consequently, when the spacer oxide film 118 is formed on the gate stacks 110 by alternately supplying trimethyl aluminum in a gaseous state and tris-(tert-alkoxy)-silanol in a gaseous state to the surface of the semiconductor substrate 100 using above PDL deposition, the spacer oxide film 118 has a uniform thickness throughout all regions of the semiconductor substrate 100 regardless of the density of the gate stacks 110.

Preferably, the formation of the spacer oxide film 118 using PDL deposition is performed at less than atmospheric pressure and at a temperature of 225˜250° C. This condition is the optimal condition for forming an oxide layer having a uniform thickness at the highest speed using the PDL deposition according one implementation of the invention.

Preferably, the surface of the semiconductor substrate 100, having a plurality of the gate stacks 110 formed thereon, is washed with an aqueous acid solution, such as an aqueous HF solution, just prior to the formation of the spacer oxide film 118. Through the above washing, the surface of the semiconductor substrate 100 is hydrated and the reactivity of the semiconductor substrate 100 with trimethyl aluminum in the gaseous state is highly improved. Thus, the spacer oxide film 118 having a uniform thickness can be formed at a higher speed using PDL deposition.

Referring back to FIG. 1D, after the formation of the spacer oxide film 118, the buffer oxide film 114 and the spacer nitride film 116 are sequentially etched, and the spacer oxide film 118 is blanket-etched according to a conventional transistor forming method, thereby forming gate spacers 120 on both side walls of the gate stacks 110. Accordingly, a plurality of gates 130 respectively comprising the gate stacks 110 and the gate spacers 120 formed on the semiconductor substrate 100 is formed. Then, a high-concentration impurity is injected into the semiconductor substrate 100 at both sides of the gates 130, thereby forming sources/drains (not shown). Thus a transistor having an LDD structure is obtained.

In the above method for forming the transistor of the semiconductor device in accordance with the preferred embodiment, a spacer oxide film 118 having a uniform thickness is formed throughout all regions of the semiconductor substrate 100 regardless of the density of the gate stacks 110. Thus, the gate spacers 120 obtained by blanket-etching the spacer oxide film 118, and the gates 130 including the gate spacers 120, also have a uniform thickness, thereby improving electrical characteristics of the transistor of the semiconductor device, for example Vt characteristics of a PMOS.

In view of the results of experimentation carried out by the present inventors, when a spacer oxide film was formed by a conventional CVD, such as an LPCVD, gate spacers and gates had a nonuniform thickness varying by region, so that a Vt difference among regions of a PMOS reaches 220 mV thereby deteriorating electrical characteristics of a transistor of a semiconductor device. On the other hand, when a spacer oxide film was formed by PDL deposition in accordance with this embodiment, gate spacers and gates had a uniform thickness throughout all regions so that a Vt difference among regions of a PMOS is only 150 mV (lowered by approximately 70 mV). Further, when the spacer oxide film was formed by conventional CVD, a Vt loading effect difference among the regions of the PMOS was 172 mV, and when the space oxide film was formed by PDL deposition, a Vt loading effect difference among the regions of the PMOS was 29 mV (lowered by approximately 140 mV).

Therefore, according to the method for forming the transistor in accordance with the embodiment described above, the electrical characteristics of the transistor, i.e., the electrical characteristics of a peri-transistor, are uniformly improved, thereby allowing the semiconductor device to be stably operated and increasing yield of the semiconductor device.

As apparent from the above description, the present invention provides a method for forming a transistor of a semiconductor device, in which gate spacers forming the transistor and gates including the gate spacers have a uniform thickness throughout all regions regardless of the density of a plurality gate stacks.

Further, since the electrical characteristics of the transistor obtained by the method of the present invention are uniformly improved, the method of the present invention allows the semiconductor device to be stably operated, thereby highly improving the quality and reliability of the semiconductor device. The method of the present invention also improves yield of the semiconductor device.

The above embodiment of the present invention has been disclosed for illustrative purposes, and those skilled in the art will appreciate that various modifications, additions, and substitutions are possible without departing from the scope of the invention as disclosed in the accompanying claims.

For example, although the above preferred embodiment has described gate spacers formed by etching a buffer oxide film, a spacer nitride film, and a spacer oxide film, the gate spacers may be made of a single film including only the spacer oxide film, or a double film including the spacer nitride film and the spacer oxide film.

What is claimed is:

1. A method for forming a transistor on a semiconductor substrate comprising:
providing the semiconductor substrate in a given environment;
forming a plurality of gate stacks over the semiconductor substrate; and
forming a spacer oxide film over the plurality of the gate stacks by alternately supplying trimethyl aluminum in a gaseous state and tris-(tert-alkoxy)-silanol in a gaseous state into the given environment wherein the semiconductor substrate is provided.

2. The method as set forth in claim 1, after the formation of the gate stacks, further comprising:
oxidizing the surfaces of a plurality of the gate stacks;
forming LDD regions at both sides of the gate stacks on the semiconductor substrate; and
sequentially forming a buffer oxide film and a spacer nitride film over a plurality of the gate stacks.

3. The method as set forth in claim 2, wherein the tris-(tert-alkoxy)-silanol is tris-(tert-butoxy)-silanol or tris-(tert-pentoxy)-silanol.

4. The method as set forth in claim 2, wherein the formation of the spacer oxide film is carried out at less than atmospheric pressure and at a temperature of 225˜250° C.

5. The method as set forth in claim 2, further comprising:
cleaning the surface of the semiconductor substrate with an aqueous acid solution prior to forming the spacer oxide film.

6. The method as set forth in claim 5, wherein the aqueous acid solution is an aqueous HF solution.

7. The method as set forth in claim 1, wherein the tris-(tert-alkoxy)-silanol is tris-(tert-butoxy)-silanol or tris-(tert-pentoxy)-silanol.

8. The method as set forth in claim 1, wherein the formation of the spacer oxide film is carried out at less than atmospheric pressure and at a temperature of 225˜250° C.

9. The method as set forth in claim 1, further comprising:
cleaning the surface of the semiconductor substrate with an aqueous acid solution prior to forming the spacer oxide film.

10. The method as set forth in claim 9, wherein the aqueous acid solution is an aqueous HF solution.
